(19) United States
(12) Patent Application Publication
(10) Pub. No.: US 2025/0351733 A1
(43) Pub. Date: Nov. 13, 2025

(54) VARIABLE RESISTANCE MEMORY DEVICE

(71) Applicant: Samsung Electronics Co., Ltd., Suwon-si (KR)

(72) Inventors: Kilho Lee, Suwon-si (KR); Yongjae Kim, Suwon-si (KR)

(21) Appl. No.: 19/019,851

(22) Filed: Jan. 14, 2025

(30) Foreign Application Priority Data
May 8, 2024 (KR) 10-2024-0060763

(51) Int. Cl. H10N 50/10; G11C 11/16; H10B 61/00; H10N 50/80

(52) U.S. Cl. CPC H10N 50/10; G11C 11/161; G11C 11/1673; G11C 11/1675; H10B 61/22; H10N 50/80

(57) ABSTRACT

A variable resistance memory device includes a first cell area including a first magnetic tunnel junction structure, a second cell area including a second magnetic tunnel junction structure having a different size from that of the first magnetic tunnel junction structure, a first peripheral circuit area electrically connected to the first cell area and having a first reference resistance value, and a second peripheral circuit area electrically connected to the second cell area and having a second reference resistance value different from the first reference resistance value.

### CROSS-REFERENCE TO RELATED APPLICATIONS

This application is based on and claims priority under 35 U.S.C. § 119 to Korean Patent Application No. 10-2024-0060763, filed on May 8, 2024, in the Korean Intellectual Property Office, the disclosure of which is incorporated by reference herein in its entirety.

### BACKGROUND

The inventive concept relates generally to a variable resistance memory device, and more particularly, to a variable resistance memory device including a magnetic tunnel junction structure.

Recently, with the trend to increase speed and lower power consumption of electronic products, fast read/write operations and low operating voltages of semiconductor devices embedded in electronic products are required. In response to these demands, highly integrated variable resistance memory devices are emerging as next-generation memory devices because they enable high-speed read and high-speed write operations and are non-volatile. In particular, research on variable resistance memory devices that utilize the magnetoresistance characteristics of a magnetic tunnel junction (MTJ) has been vigorously conducted.

### SUMMARY

The inventive concept provides a variable resistance memory device which includes cell areas respectively having magnetic tunnel junction structures of different sizes, and has high speed and improved data retention characteristics.

In addition, objectives to be solved by the inventive concept are not limited to the above-mentioned ones, and other objectives may be clearly understood by those skilled in the art from the description below.

According to an aspect of the inventive concept, there is provided a variable resistance memory device including a first cell area including a first magnetic tunnel junction structure, a second cell area including a second magnetic tunnel junction structure having a different size from that of the first magnetic tunnel junction structure, a first peripheral circuit area connected to the first cell area and having a first reference resistance value, and a second peripheral circuit area connected to the second cell area and having a second reference resistance value different from the first reference resistance value.

According to another aspect of the inventive concept, there is provided a variable resistance memory device including a first cell area including a first magnetic tunnel junction structure, and a second cell area including a second magnetic tunnel junction structure, wherein a lower portion of the first magnetic tunnel junction structure is electrically connected to a first cell plug through a first pad electrode, and a lower portion of the second magnetic tunnel junction structure is electrically connected to a second cell plug through a second pad electrode, and a diameter of the second magnetic tunnel junction structure is greater than a diameter of the first magnetic tunnel junction structure, and a diameter of the second pad electrode is greater than a diameter of the first pad electrode.

According to another aspect of the inventive concept, there is provided a variable resistance memory device including a first cell area including a first magnetic tunnel junction structure, a second cell area including a second magnetic tunnel junction structure having a different size from that of the first magnetic tunnel junction structure, a first peripheral circuit area connected to the first cell area and having a first reference resistance value, and a second peripheral circuit area connected to the second cell area and having a second reference resistance value different from the first reference resistance value, wherein the first cell area includes a first cell plug and a first lower insulating layer covering the first cell plug, a first pad electrode penetrating the first lower insulating layer and electrically connecting a lower portion of the first magnetic tunnel junction structure to the first cell plug, and a first contact structure electrically connecting an upper portion of the first magnetic tunnel junction structure to a bit line, the second cell area includes a second cell plug and a second lower insulating layer covering the second cell plug, a second pad electrode penetrating (i.e., extending in) the second lower insulating layer and electrically connecting a lower portion of the second magnetic tunnel junction structure to the second cell plug, and a second contact structure electrically connecting an upper portion of the second magnetic tunnel junction structure to a bit line, a diameter of the first magnetic tunnel junction structure has a greater value than a diameter of the second magnetic tunnel junction structure, and the first peripheral circuit area includes a first reference resistance circuit having a first reference resistance range, and the second peripheral circuit area includes a second reference resistance circuit having a second reference resistance range different from the first reference resistance range, and the first reference resistance circuit is configured such that the first reference resistance value is optimized to a value between a high resistance value and a low resistance value of the first magnetic tunnel junction structure, and the second reference resistance circuit is configured such that the second reference resistance value is greater than the first reference resistance value and is optimized to a value between a high resistance value and a low resistance value of the second magnetic tunnel junction structure, and a diameter of the second pad electrode is greater than a diameter of the first pad electrode.

### BRIEF DESCRIPTION OF THE DRAWINGS

Embodiments will be more clearly understood from the following detailed description taken in conjunction with the accompanying drawings, wherein like reference numerals (when used) indicate corresponding elements throughout the several views, and in which:

FIG. 1 is a circuit diagram illustrating a cell array of a variable resistance memory device according to an embodiment;

FIG. 2 is a circuit diagram illustrating a magnetoresistive memory cell of FIG. 1;

FIG. 3 is a schematic perspective view illustrating the magnetoresistive memory cell of FIG. 2;

FIGS. 4A and 4B are conceptual diagrams to describe data stored according to a magnetization direction in the magnetic tunnel junction of FIG. 3;

FIGS. 5A and 5B are circuit diagrams and resistance graphs, respectively, for describing the principle of sensing resistance in the variable resistance memory device of FIG. 1;

FIG. 6 is a schematic plan view to describe a variable resistance memory device according to an embodiment of the inventive concept;

FIG. 7 is a schematic cross-sectional view illustrating a first cell area of a variable resistance memory device according to an embodiment of the inventive concept;

FIG. 8 is a schematic cross-sectional view illustrating a second cell area of a variable resistance memory device according to an embodiment of the inventive concept;

FIG. 9 is a diagram to describe the different sizes of a first magnetic tunnel junction structure and a second magnetic tunnel junction structure according to an embodiment of the inventive concept;

FIG. 10 is a circuit diagram illustrating an example methodology for optimizing a reference resistance range of a variable resistance memory device according to an embodiment of the inventive concept; and

FIG. 11 is a schematic plan view of a variable resistance memory device according to an embodiment of the inventive concept.

### DETAILED DESCRIPTION

Hereinafter, embodiments of the inventive concept will be described more fully with reference to the accompanying drawings. In the drawings, like elements are labeled like reference numerals and repeated descriptions thereof will be omitted.

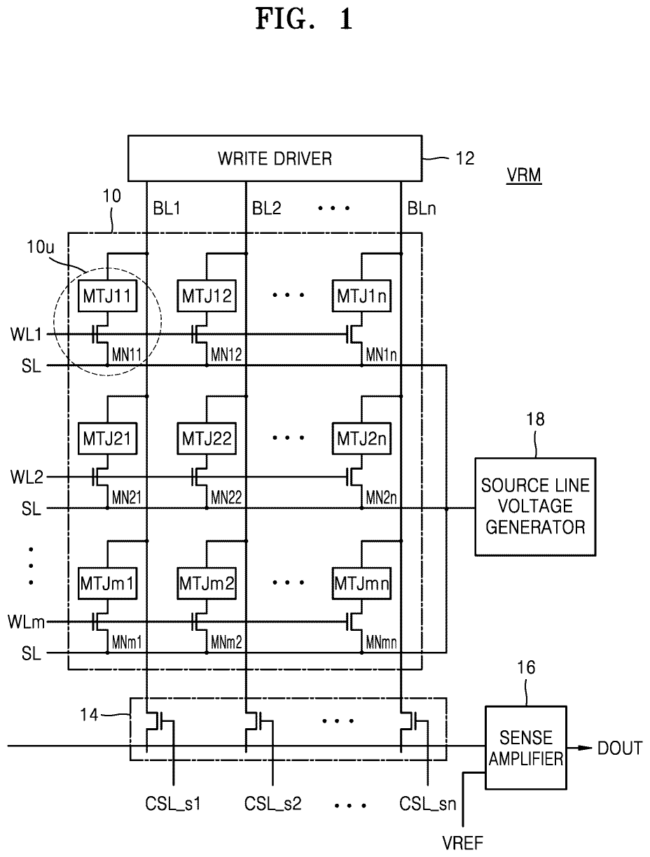

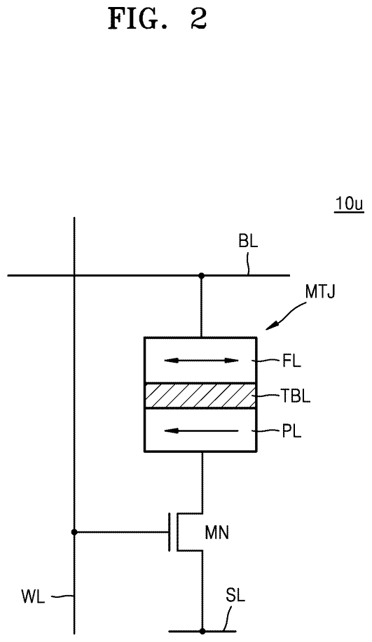

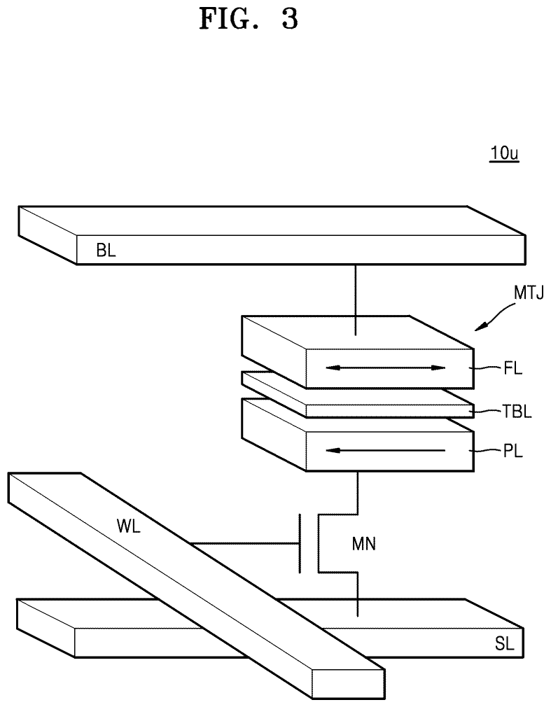

FIG. 1 is a circuit diagram illustrating a cell array of a variable resistance memory device VRM according to an embodiment. FIG. 2 is a circuit diagram illustrating a magnetoresistive memory cell of FIG. 1. FIG. 3 is a perspective view illustrating the magnetoresistive memory cell of FIG. 2.

Referring to FIGS. 1 to 3, the variable resistance memory device VRM may be a magnetoresistive memory device as an embodiment.

As illustrated in FIG. 1, the magnetoresistive memory device may be a magnetoresistive random-access memory (MRAM). The variable resistance memory device VRM may include a magnetic tunnel junction MTJ, which has a variable resistance layer.

The variable resistance memory device VRM may include a magnetoresistive memory cell array 10. The magnetoresistive memory cell array 10 may also be referred to as a cell array. The magnetoresistive memory cell array 10 may be electrically connected to a write driver 12, a selection circuit 14, a source line voltage generator 18, and a sense amplifier 16. The term “connected” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items.

The magnetoresistive memory cell array 10 may include a plurality of magnetoresistive memory cells 10u. The magnetoresistive memory cell 10u may be simply referred to as a memory cell. The magnetoresistive memory cell array 10 may include a plurality of word lines WL1 to WLm, where m is an integer greater than 1, and a plurality of bit lines BL1 to BLn, where n is an integer greater than 1. The magnetoresistive memory cell array 10 may have a magnetoresistive memory cell 10u between each of the plurality of word lines WL1 to WLm and each of the plurality of bit lines BL1 to BLn.

The magnetoresistive memory cell array 10 may include a plurality of cell transistors MN11 to MNmn having respective gates connected to the plurality of word lines WL1 to WLm and a plurality of magnetic tunnel junctions MTJ11 to MTJmn which are connected between each of the plurality of cell transistors MN11 to MNmn and each of the plurality of bit lines BL1 to BLn and constitute a variable resistance layer.

When the write driver 12 is connected to the plurality of bit lines BL1 to BLn, the write driver 12 generates a program current based on write data and provides a program current to the plurality of bit lines BL1 to BLn.

The selection circuit 14 may selectively connect the plurality of bit lines BL1 to BLn to the sense amplifier 16 in response to a plurality of column selection signals CSL_s1 to CSL_sn. The sense amplifier 16 may generate output data DOUT by amplifying a difference between an output voltage signal of the selection circuit 14 and a reference voltage VREF.

Respective sources of the plurality of cell transistors MN11 to MNmn may be electrically connected to a common source line SL. In order to magnetize the plurality of magnetic tunnel junctions MTJ11 to MTJmn in the magnetoresistive memory cell array 10, a voltage higher than a voltage applied to the plurality of bit lines BL1 to BLn may be applied to the source line SL. The source line voltage generator 18 may generate a source line driving voltage VSL and provide the same to the source line SL of the magnetoresistive memory cell array 10.

In FIGS. 2 and 3, for convenience, the magnetic tunnel junction MTJ11, the cell transistor MN11, the word line WL1, and the bit line BL1 of the magnetoresistive memory cell 10u of FIG. 1 are shown as a magnetic tunnel junction MTJ, a cell transistor MN, a word line WL, and a bit line BL, respectively.

As illustrated in FIG. 2, the magnetoresistive memory cell 10u may include, for example, the cell transistor MN including an NMOS transistor and the magnetic tunnel junction MTJ. The cell transistor MN has a gate connected to the word line WL and a source connected to the source line SL. The magnetic tunnel junction MTJ is connected between a drain region of the cell transistor MN and the bit line BL.

As illustrated in FIG. 3, the magnetic tunnel junction MTJ may include a pinned layer PL having a fixed, constant magnetization direction (indicated by a one-way arrow), a free layer FL that is magnetized toward a magnetic field applied from the outside (indicated by a two-way arrow), and a tunnel barrier layer TBL formed as an insulating layer between the pinned layer PL and the free layer FL. The pinned layer PL may be connected to the drain region of the cell transistor MN, and the free layer FL may be connected to the bit line BL. Additionally, a source region of the cell transistor MN may be connected to the source line SL, and a gate of the cell transistor MN may be connected to the word line WL. Meanwhile, for example, an anti-ferromagnetic layer may be further provided to fix the magnetization direction of the pinned layer PL.

In some embodiments, the pinned layer PL may include any one of iron manganese (FeMn), iridium manganese (IrMn), platinum manganese (PtMn), manganese oxide (MnO), manganese sulfide (MnS), manganese tellurium (MnTe), manganese fluoride (MnF₂), iron fluoride (FeF₂), iron chloride (FeCl₂), iron oxide (FeO), cobalt chloride (CoCl₂), cobalt oxide (CoO), nickel chloride (NiCl₂), nickel oxide (NiO), chromium (Cr), iron (Fe), nickel (Ni), cobalt (Co), ruthenium (Ru), iridium (Ir), and rhodium (Rh), although embodiments are not limited thereto.

In some embodiments, the free layer FL may include a ferromagnetic material including at least one of iron (Fe), nickel (Ni), or cobalt (Co).

In some embodiments, the tunnel barrier layer TBL may include aluminum oxide (AlO) or magnesium oxide (MgO), although embodiments are not limited thereto.

The materials constituting a resistance layer of MRAM have a variable resistance value according to the magnitude and/or direction of a current or voltage, and may have non-volatile properties of maintaining the resistance value even when the current or voltage is cut off.

For reference, to describe the overall characteristics of MRAM, MRAM is a non-volatile memory device based on magneto-resistance. MRAM may differ from volatile RAM in several ways. For example, because MRAM is non-volatile, MRAM may retain its memory contents even when a power supply for a memory device is turned off. Although non-volatile RAM is generally said to be slower than volatile RAM, MRAM may have read and write response times comparable to those of volatile RAM. For example, MRAM may be an all-purpose memory device that has the cost-effectiveness and high capacity characteristics of dynamic RAM (DRAM), the high-speed operation characteristics of static RAM (SRAM), and the non-volatile characteristics of flash memory.

Unlike typical RAM technology where data is stored as electric charges, MRAM may store data via magneto-resistance elements. Generally, magneto-resistance elements of MRAM may include two magnetic layers, and each magnetic layer may be magnetized in either of two directions. For example, MRAM may be a non-volatile memory device that reads and writes data using a magnetic tunnel junction that includes two magnetic layers and an insulating film sandwiched between them. A resistance value of the magnetic tunnel junction may vary depending on a magnetization direction of a magnetic layer. Using this difference in resistance value, data may be programmed, stored, or deleted.

In MRAM, the magnetization direction of the magnetic layer may be changed using the spin transfer torque (STT) phenomenon. The STT phenomenon refers to a phenomenon in which a magnetization direction of a magnetic layer changes due to spin transfer of electrons when a spin-polarized current in one direction flows. Accordingly, MRAM using the STT phenomenon is also called STT-RAM or STT-MRAM. Typical STT-MRAM may include a magnetic tunnel junction MTJ. As described above, the magnetic tunnel junction MTJ may include the free layer FL, the pinned layer PL, and the tunnel barrier layer TBL.

In the magnetic tunnel junction MTJ, a magnetization direction of the pinned layer PL is fixed, and a magnetization direction of the free layer FL may be changed by an applied program current (i.e., bias). Through the program current, magnetization directions of two magnetic layers (the pinned layer PL and the free layer FL) may be arranged to be parallel or anti-parallel by changing the magnetization direction of the free layer FL. If the magnetization directions of the magnetic layers are parallel to one another, it may represent a low (“0”) logic state in which the resistance between the two magnetic layers is relatively low, and if the magnetization directions of the magnetic layers are anti-parallel to one another, it may represent a high (“1”) logic state in which the resistance between the two magnetic layers is relatively high. Switching the magnetization direction of the free layer FL and a high-resistance or low-resistance state between the magnetic layers as a result may provide write and read operations of the MRAM.

For reference, in the case of toggle-type MRAM, which switches the magnetization direction of the free layer by a magnetic field generated by a program current, scaling limitations are encountered due to write disturbance. Write disturbance refers to a phenomenon where, when multiple cells are arranged in an MRAM cell array, a program current of MRAM is relatively large, and accordingly, the program current applied to one memory cell causes a field change in a free layer of an adjacent cell. This write disturbance may be solved to some extent by using the STT phenomenon.

For STT-MRAM, program current typically flows through a magnetic tunnel junction MTJ. The pinned layer PL may polarize the electron spin of the program current, and torque may be generated as the spin-polarized electron current passes through the magnetic tunnel junction MTJ. Spin-polarized electron currents may interact with the free layer FL, exerting a torque on the free layer FL. If the torque of the spin-polarized electron current passing through the magnetic tunnel junction MTJ is greater than a critical switching current density, the torque exerted by the spin-polarized electron current is sufficient to switch the magnetization direction of the free layer FL. Accordingly, the magnetization direction of the free layer FL may be arranged parallel or anti-parallel with respect to the pinned layer PL, and a resistance state of the magnetic tunnel junction MTJ changes.

In this way, since STT-MRAM switches the magnetization direction of the free layer FL through spin-polarized electron current, there is no need to generate a magnetic field by applying a large current to switch the magnetization direction of the free layer FL. Accordingly, STT-MRAM may contribute to reducing program current along with a reducing cell size, and may also solve the write disturbance problem. Additionally, STT-MRAM enables a high tunnel magneto-resistance ratio and has a high ratio between high-resistance and low-resistance states, which may improve read operations within a magnetic domain.

The word line WL is enabled by a row decoder and may be connected to a word line driver that drives a word line selection voltage. The word line selection voltage may activate the word line WL to perform a read or write operation of a logic state through a magnetic tunnel junction MTJ.

The source line SL may be connected to a source line circuit. The source line circuit may receive an address signal and a read/write signal, decode the same, and apply a source line selection signal to the selected source line SL. A ground reference voltage may be applied to unselected source lines SL.

The bit line BL may be connected to the selection circuit 14 (see FIG. 1) driven by the column selection signals CSL_s1 to CSL_sn (see FIG. 1). The column selection signals CSL_s1 to CSL_sn may be selected by a column decoder. For example, a selected column selection signal may turn on a column selection transistor in the selection circuit 14 and select the bit line BL. The logic state of the magnetic tunnel junction MTJ may be output to the bit line BL selected through a read operation through the sense amplifier 16 (see FIG. 1). Additionally, a write current may be transferred to the selected bit line BL through a write operation, thereby storing a logic state in the magnetic tunnel junction MTJ.

For reference, in order to store logic states of “0” and “1” in the magnetic tunnel junction MTJ, which is a memory device of MRAM, a current flowing through the magnetic tunnel junction MTJ is to be bidirectional. That is, the current flowing through the magnetic tunnel junction MTJ when writing data “0” and when writing data “1” is to be in opposite directions. In order to have a structure that allows current to flow in the opposite direction, MRAM has the source line SL in addition to the bit line BL to change a potential difference between the magnetic tunnel junction MTJ and the cell transistor MN, thereby enabling to select a direction of current flowing through the magnetic tunnel junction MTJ.

For a write operation of STT-MRAM, a logic high voltage is applied to the word line WL1 to turn on the cell transistor MN11, and a write current is applied between the bit line BL1 and the source line SL (see FIG. 1).

For a read operation of STT-MRAM, a logic high voltage is applied to the word line WL1 to turn on the cell transistor MN11, and a read current is applied from the bit line BL1 to the source line SL (see FIG. 1). Thus, data stored in the magnetoresistive memory cell 10u may be determined according to a resistance value of the magnetic tunnel junction MTJ11 with respect to the read current.

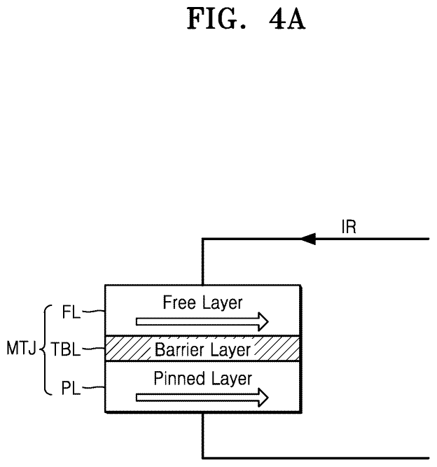

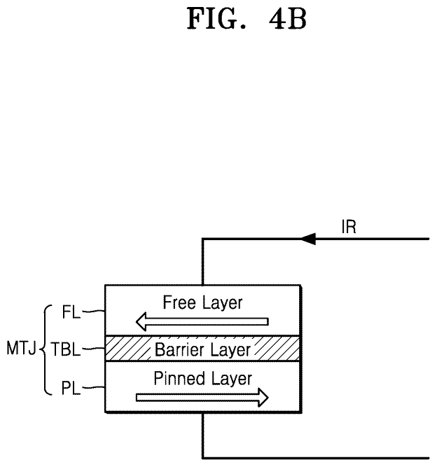

FIGS. 4A and 4B are conceptual diagrams to describe a manner in which data is stored according to magnetization direction in the magnetic tunnel junction of FIG. 3.

Referring to FIGS. 4A and 4B, a resistance value of the magnetic tunnel junction MTJ may vary depending on the magnetization direction of the free layer FL. When a read current IR flows through the magnetic tunnel junction MTJ, a data voltage according to the resistance value of the magnetic tunnel junction MTJ may be output. Since the intensity of the read current IR is much smaller than the intensity of the write current, the magnetization direction of the free layer FL does not change due to the read current IR.

As illustrated in FIG. 4A, in the magnetic tunnel junction MTJ, the magnetization direction of the free layer FL and the magnetization direction of the pinned layer PL may be arranged in parallel. The magnetic tunnel junction MTJ in this state may have a low resistance value, and thus data “0” may be output through a read operation.

As illustrated in FIG. 4B, in the magnetic tunnel junction MTJ, the magnetization direction of the free layer FL and the magnetization direction of the pinned layer PL may be arranged to be anti-parallel. The magnetic tunnel junction MTJ in this state may have a high resistance value, and thus data “1” may be output through a read operation.

Here, a horizontal magnetic element in which the magnetization directions of the free layer FL and the pinned layer PL of the magnetic tunnel junction MTJ11 are horizontal is illustrated, but in other embodiments, a vertical magnetic element in which the magnetization directions of the free layer FL and the pinned layer PL are vertical may also be used.

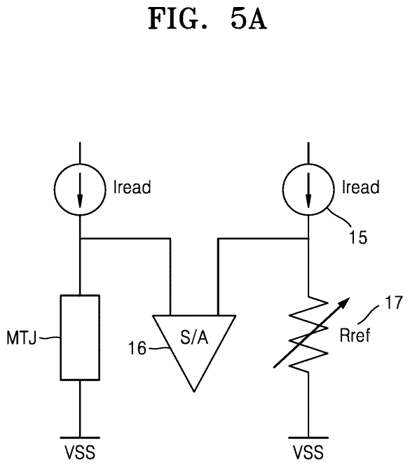

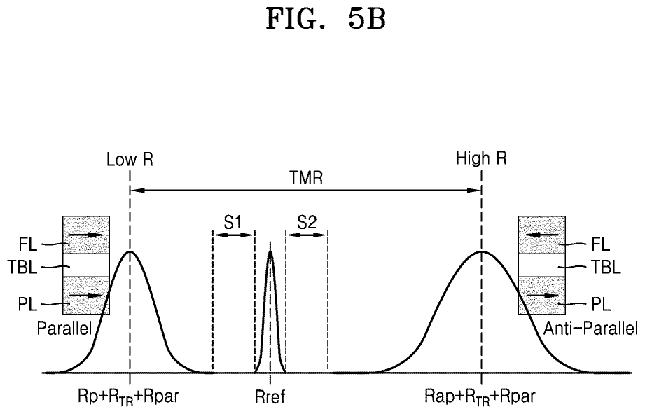

FIGS. 5A and 5B are circuit diagrams and resistance graphs, respectively, for describing the principle of sensing resistance in the variable resistance memory device of FIG. 1. In FIG. 5B, the x-axis represents the resistance value and the unit thereof is an arbitrary unit. The y-axis represents the number of cells with a corresponding resistance value, and may have the form of a normal distribution as shown.

Referring to FIGS. 5A and 5B, as described above, in order to read data in the magnetic tunnel junction MTJ, that is, to sense a logic state of the magnetic tunnel junction MTJ, a read current Iread may be applied to the magnetic tunnel junction MTJ. Accordingly, a voltage may be developed across the magnetic tunnel junction MTJ and may be sensed by the sense amplifier (S/A) 16. In addition, the read current Iread may be applied by a current source 15 to the reference voltage generator 17 and a reference voltage may be developed and sensed by the sense amplifier 16. To determine the logic state stored in the magnetic tunnel junction MTJ, a voltage across the magnetic tunnel junction MTJ in the sense amplifier 16 may be compared with a voltage of the reference voltage generator 17. According to a result of the comparison, the logic state of the magnetic tunnel junction MTJ, that is, data stored in the magnetic tunnel junction MTJ, may be determined.

As described above, when the magnetization direction of the free layer FL and the magnetization direction of the pinned layer PL are arranged in parallel, the magnetic tunnel junction MTJ may have a low resistance value (Low R). On the other hand, when the magnetization direction of the free layer FL and the magnetization direction of the pinned layer PL are arranged anti-parallel, the magnetic tunnel junction MTJ may have a high resistance value (High R). The voltage developed across the MTJ and sensed by the sense amplifier 16 will be dependent on the resistance of the MTJ; the voltage developed across the MTJ in its low-resistance state will be less than the voltage developed across the MTJ in its high-resistance state for a given read current Iread.

For reference, the voltage sensed by the sense amplifier 16 may not only be a resistance of the magnetic tunnel junction MTJ, but also a voltage due to the cell transistor MN and parasitic resistance. Accordingly, in the graph of FIG. 5B, Rp may represent a resistance of a parallel state of the magnetic tunnel junction MTJ, Rap may represent an anti-parallel state of the magnetic tunnel junction MTJ, and R_{TR} may represent a resistance of the cell transistor MN, and Rpar may represent parasitic resistance.

Tunnel magneto-resistance (TMR) may be defined as (Rap−Rp)/Rp, and the greater the TMR, the greater a gap between the low resistance value (Low R) and the high resistance value (High R) may be. Additionally, when TMR is relatively large, a reference resistance value Rref may be arranged with sufficient intervals (S1, S2) for each of the low resistance value (Low R) and the high resistance value (High R). Accordingly, the resistance state of the magnetic tunnel junction MTJ and the resulting logic state of the magnetic tunnel junction MTJ may be sensed clearly.

If TMR is relatively small or the reference resistance value Rref is placed biased to one side, the resistance state of the magnetic tunnel junction MTJ and a resulting logic state of the magnetic tunnel junction MTJ may not be sensed accurately or may be sensed incorrectly. For example, if a wiring for a reference line is damaged and the resistance increases, the reference resistance value Rref may increase. In this case, the accuracy of sensing the logic state of the magnetic tunnel junction MTJ may be reduced. In addition, when the reference resistance value Rref exceeds the high resistance value (High R), the resistance state of the magnetic tunnel junction MTJ of all cells is determined to be the low resistance value (Low R), and the logic state of the magnetic tunnel junction MTJ may not be sensed at all. As a result, reliability of information storage devices including the magnetic tunnel junction MTJ deteriorates, which may lead to a decrease in the yield of the entire memory device.

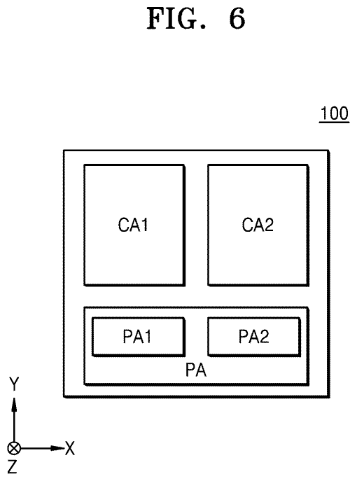

FIG. 6 is a schematic plan view to describe a variable resistance memory device according to an embodiment.

As illustrated in FIG. 6, the variable resistance memory device 100 may include a first cell area CA1, a second cell area CA2, and a peripheral circuit area PA.

Each of the first and second cell areas CA1 and CA2 may include an area in which the magnetoresistive memory cell array 10 of FIG. 1 is disposed. Additionally, the cell areas CA1, CA2 may be an area in which the magnetoresistive memory cell 10u described with reference to FIGS. 1 and 2 is disposed.

In the peripheral circuit area PA, peripheral circuits and peripheral transistors that control the magnetoresistive memory cell array 10 of the first and second cell areas CA1 and CA2 may be disposed. That is, the peripheral circuit area PA may be an area in which core/peri circuits are arranged. The peripheral circuit area PA may include a first peripheral circuit area PA1 and a second peripheral circuit area PA2. The first peripheral circuit area PA1 may be electrically connected to the first cell area CA1, and the second peripheral circuit area PA2 may be electrically connected to the second cell area CA2. That is, the first cell area CA1 and the second cell area CA2 share a portion of the peripheral circuit area PA, but the first peripheral circuit area PA1 may be connected only to the first cell area CA1, and the second peripheral circuit area PA2 may be connected only to the second cell area CA2. The functions of the first peripheral circuit area PA1 and the second peripheral circuit area PA2 will be described later.

In FIG. 6, the peripheral circuit area PA is illustrated as being disposed at one side spaced apart from the first cell area CA1 and the second cell area CA2 in the Y direction, but is not limited thereto, and the peripheral circuit area PA may also be disposed to surround the first cell area CA and the second cell area CA2. The term “surround” (or “surrounding,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. Additionally, in some embodiments, the variable resistance memory device 100 may include a boundary area between the first cell area CA1 and the second cell area CA2 and the peripheral circuit area PA.

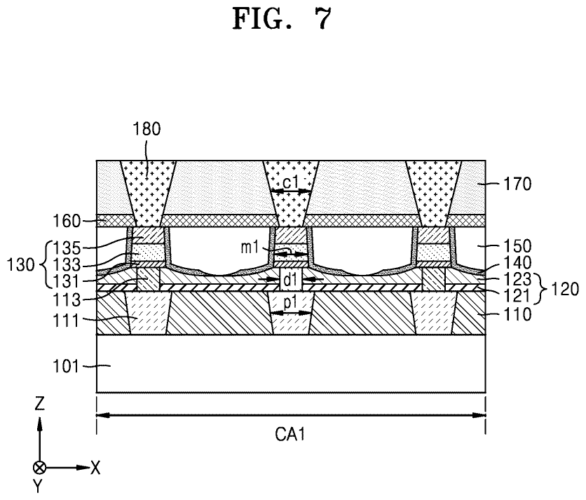

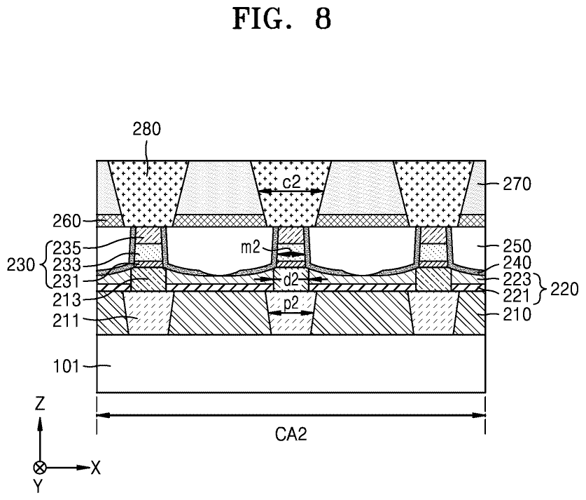

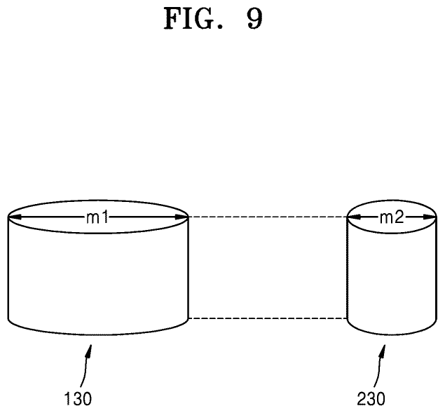

FIG. 7 is a schematic cross-sectional view illustrating a first cell area of a variable resistance memory device according to an embodiment. FIG. 8 is a schematic cross-sectional view illustrating a second cell area of a variable resistance memory device according to an embodiment. FIG. 9 is a diagram to describe the different sizes of a first magnetic tunnel junction structure and a second magnetic tunnel junction structure according to an embodiment.

Referring to FIGS. 7 to 9, the first cell area CA1 of the variable resistance memory device 100 (see FIG. 6) may include a substrate 101, a base insulating layer 110, a lower insulating layer 120, a first magnetic tunnel junction structure 130, a capping pattern 140, an interlayer insulating layer 150, an etch stop layer 160, an upper insulating layer 170, and a first contact structure 180, and the second cell area CA2 of the variable resistance memory device 100 may include the substrate 101, a base insulating layer 210, a lower insulating layer 220, a second magnetic tunnel junction structure 230, a capping pattern 240, an interlayer insulating layer 250, an etch stop layer 260, an upper insulating layer 270, and a second contact structure 280. The first cell area CA1 and the second cell area CA2 may have the same configuration, and some of the elements thereof may have different sizes. Therefore, the following description will focus on the configuration of the first cell area CA1, and on the difference(s) between the second cell area CA2 and the first cell area CA1.

The substrate 101 of the variable resistance memory device 100 may include a semiconductor wafer including, for example, silicon (Si), germanium (Ge), silicon carbide (SiC), gallium arsenide (GaAs), indium arsenide (InAs), or indium phosphorus (InP), although embodiments are not limited thereto. In some embodiments, the substrate 101 may include an impurity-doped well or an impurity-doped structure, which is a conductive region.

Although not explicitly shown, a cell transistor may be formed on the substrate 101 in the first cell area CA1. For example, the cell transistor may be configured as a buried gate type transistor. Additionally, a peripheral circuit transistor may be formed on the substrate 101 in the peripheral circuit area (PA, see FIG. 6). For example, the peripheral circuit transistor may be configured as a planar-type transistor.

The base insulating layer 110 may be disposed on the substrate 101, and a plurality of first cell plugs 111 penetrating (i.e., extending in) the base insulating layer 110 in the Z direction (i.e., vertical direction) may be disposed. The plurality of first cell plugs 111 may be connected to the cell transistor or to a lower metal line (not shown) in the first cell area CA1.

The lower insulating layer 120 covering the plurality of first cell plugs 111 may be disposed on the substrate 101. The term “covering” (or “covers,” or like terms), as may be used herein, is intended to broadly refer to an element, structure or layer that is on or over another element, structure or layer, either directly or with one or more other intervening elements, structures or layers therebetween. The lower insulating layer 120 may include a first lower insulating layer 121 and a second lower insulating layer 123 formed on the first lower insulating layer 121. The first lower insulating layer 121 and the second lower insulating layer 123 may include different materials. In some embodiments, the first lower insulating layer 121 may include, for example, a SiCN film, a SiOC film, a SiOF film, a SiCH film, a SiOCH film, or a combination thereof. The second lower insulating layer 123 may include a tetraethoxysilane (TEOS) film, but is not limited thereto.

A plurality of first pad electrodes 113 that penetrate the lower insulating layer 120 to contact and are electrically connected to the plurality of first cell plugs 111 may be provided.

A plurality of first magnetic tunnel junction structures 130 may be in contact with and electrically connected to the plurality of first pad electrodes 113. In some embodiments, the plurality of first magnetic tunnel junction structures 130 may be disposed on cross points in a mesh structure in a first horizontal direction (X direction) and a second horizontal direction (Y direction). Additionally, the plurality of first magnetic tunnel junction structures 130 may form a memory cell.

The plurality of first magnetic tunnel junction structures 130 may be formed on the plurality of first cell plugs 111 in the first cell area CA1. That is, the plurality of first magnetic tunnel junction structures 130 may be electrically connected to the plurality of first cell plugs 111 through the plurality of first pad electrodes 113.

Each of the plurality of first magnetic tunnel junction structures 130 may have a structure in which a lower electrode 131, a magnetic tunnel junction pattern 133, and an upper electrode 135 are sequentially stacked in the Z direction. The magnetic tunnel junction pattern 133 constitutes a variable resistance layer and may include the pinned layer PL, the tunnel barrier layer TBL, and the free layer FL, as previously described with reference to FIGS. 2 and 3. The lower electrode 131 and the upper electrode 135 may include a conductive material such as a metal.

The capping patterns 140 may be disposed on both (opposing) side walls of each of the plurality of first magnetic tunnel junction structures 130. The capping pattern 140 may include an insulating material.

The interlayer insulating layer 150 may be disposed to fill a space between the plurality of first magnetic tunnel junction structures 130 without voids. In some embodiments, the interlayer insulating layer 150 may include a material with a dielectric constant that is lower than that of silicon oxide.

The etch stop layer 160 may be disposed to expose an upper surface of the first magnetic tunnel junction structure 130 and an uppermost surface of the capping pattern 140 and cover the interlayer insulating layer 150. The term “expose” (or “exposed,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device.

The upper insulating layer 170 may be disposed to cover the etch stop layer 160. In some embodiments, the upper insulating layer 170 may include a TEOS film, but is not limited thereto. In other embodiments, the upper insulating layer 170 may include, for example, a SiCN film, a SiOC film, a SiOF film, a SiCH film, a SiOCH film, or a combination thereof.

The first contact structure 180 may be in contact with the first magnetic tunnel junction structure 130 in the first cell area CA1. The first contact structure 180 may contact a portion of the sidewall and an upper surface of the upper electrode 135 of the first magnetic tunnel junction structure 130 exposed from the capping pattern 140.

Although not explicitly shown, a contact structure in contact with a peripheral plug may be disposed in the peripheral circuit area (PA, see FIG. 6).

The lower insulating layer 220 included in the second cell area CA2 may include a first lower insulating layer 221 and a second lower insulating layer 223 formed on the first lower insulating layer 221. The first lower insulating layer 221 and the second lower insulating layer 223 may include different materials. The second magnetic tunnel junction structures 230 in the second cell area CA2 may have a structure in which a lower electrode 231, a magnetic tunnel junction pattern 233, and an upper electrode 235 are sequentially stacked in the Z direction. The magnetic tunnel junction pattern 233 constitutes a variable resistance layer and may include the pinned layer PL, the tunnel barrier layer TBL, and the free layer FL, as previously described with reference to FIGS. 2 and 3. The lower electrode 231 and the upper electrode 235 may include a conductive material such as a metal.

The second magnetic tunnel junction structure 230 included in the second cell area CA2 may have a different size from that of the first magnetic tunnel junction structure 130 included in the first cell area CA1. For example, the first magnetic tunnel junction structure 130 and the second magnetic tunnel junction structure 230 may have different diameters and the same height.

As a diameter of the magnetic tunnel junction MTJ increases, the resistance decreases and data retention characteristics improve, but the speed decreases, which is similar to flash memory. Conversely, as the diameter of the magnetic tunnel junction MTJ decreases, resistance increases, increasing the speed but reducing the data retention characteristics, which are similar characteristics to those of SRAM.

A variable resistance memory device according to an embodiment includes the first magnetic tunnel junction structure 130 and the second magnetic tunnel junction structure 230 of different sizes arranged on one chip so as to implement two characteristics at the same time: high data retention and high speed. That is, the first cell area CA1 including the first magnetic tunnel junction structure 130 and the second cell area CA2 including the second magnetic tunnel junction structure 230 of a different size from that of the first magnetic tunnel junction structure 130 are disposed on a single substrate, the substrate 101, and thus, various magnetic tunnel junction MTJ characteristics may be secured. A variable resistance memory device having various magnetic tunnel junction MTJ characteristics may operate as a memory device by using the data retention characteristics and as a logic device using the high speed characteristics. According to embodiments, at least one of the first cell area CA1 and the second cell area CA2 may include a logic circuit.

Referring to FIGS. 6 to 9, a diameter m1 of the first magnetic tunnel junction structure 130 may have a greater value than a diameter m2 of the second magnetic tunnel junction structure 230. Thus, a second writing speed of the second magnetic tunnel junction structure 230 may be faster than a first writing speed of the first magnetic tunnel junction structure 130. Second data retention characteristics of the second magnetic tunnel junction structure 230 may be lower than first data retention characteristics of the first magnetic tunnel junction structure 130. Thus, a data retention period of the second magnetic tunnel junction structure 230 may be shorter than a data retention period of the first magnetic tunnel junction structure 130.

According to an embodiment, the first cell area CA1 has a smaller MTJ resistance than the second cell area CA2, and accordingly, a read margin of the first cell area CA1 is reduced. Therefore, when the first cell area CA1 and the second cell area CA2 having different MTJ resistances are implemented in one chip, different reference resistance values Rref (see FIG. 5B) may have to be applied to the first cell area CA1 and the second cell area CA2. Additionally, the MTJ resistance of the second cell area CA2 increases compared to the first cell area CA1, thereby increasing a switching voltage. If the switching voltage increases, switching may become difficult, and to compensate for this, the parasitic resistance value (Rpar, see FIG. 5B) of the second cell area CA2 needs to be adjusted to be smaller than that of the first cell area CA1.

In the variable resistance memory device 100 according to an embodiment, in order for the parasitic resistance value of the second cell area CA2 to be implemented to be smaller than the parasitic resistance value of the first cell area CA1, the second cell area CA2 may have a larger contact size than the first cell area CA1. As described above, the first magnetic tunnel junction structure 130 may be electrically connected to a bit line through the first contact structure 180 at the top, and may be electrically connected to the first cell plug 111 through the first pad electrode 113 at the bottom. Likewise, the second magnetic tunnel junction structure 230 may be electrically connected to a bit line through the second contact structure 280 at the top, and may be electrically connected to a second cell plug 211 through a second pad electrode 213 at the bottom.

According to embodiments, a size of the second pad electrode 213 connected to the second magnetic tunnel junction structure 230 may be formed to be greater than a size of the first pad electrode 113 connected to the first magnetic tunnel junction structure 130. For example, a diameter d2 of the second pad electrode 213 may have a greater value than a diameter d1 of the first pad electrode 113.

According to embodiments, the size of the second cell plug 211 connected to the second magnetic tunnel junction structure 230 may be formed to be greater than the size of the first cell plug 111 connected to the first magnetic tunnel junction structure 130. For example, an average diameter p2 of the second cell plug 211 may have a greater value than an average diameter p1 of the first cell plug 111. The term “average diameter” as used herein is intended to refer to an average diameter in the horizontal direction (i.e., X and/or Y direction) of the structure (e.g., first cell plug 111 or second cell plug 211) across the overall height of the structure in the vertical direction (Z direction).

According to embodiments, a size of the second contact structure 280 connected to the second magnetic tunnel junction structure 230 may be formed to be greater than a size of the first contact structure 180 connected to the first magnetic tunnel junction structure 130. For example, an average diameter c2 of the second contact structure 280 may have a greater value than an average diameter c1 of the first contact structure 180.

The first cell area CA1 and the second cell area CA2 may share a portion of the peripheral circuit area PA. However, since the first cell area CA1 and the second cell area CA2 have different MTJ resistances, a reference resistance value is to be determined by optimizing a reference resistance range for separating an MTJ resistance distribution in a parallel state and an MTJ resistance distribution in an anti-parallel state. The peripheral circuit area PA may include the first peripheral circuit area PA1 connected only to the first cell area CA1 and the second peripheral circuit area PA2 connected only to the second cell area CA2. The first peripheral circuit area PA1 may optimize a first reference resistance value of the first magnetic tunnel junction structure 130, and the second peripheral circuit area PA2 may optimize a second reference resistance value of the second magnetic tunnel junction structure 230. That is, the first reference resistance value of the first peripheral circuit area PA1 connected to the first cell area CA1 may be different from the second reference resistance value of the second peripheral circuit area PA2 connected to the second cell area CA2.

According to an embodiment, a diameter m1 of the first magnetic tunnel junction structure 130 may be formed to be greater than a diameter m2 of the second magnetic tunnel junction structure 230, and thus, when the resistance of the first magnetic tunnel junction structure 130 is less than the resistance of the second magnetic tunnel junction structure 230, the first reference resistance value may have a value less than the second reference resistance value. The first reference resistance value may be optimized to be a value between a relatively high resistance value of the first magnetic tunnel junction structure 130—that is, a resistance value when the magnetization directions of the free layer and the pinned layer are anti-parallel—and be a relatively low resistance value-that is, a resistance value when the magnetization directions of the free layer and the pinned layer are parallel. The second reference resistance value may be optimized to be a value between a high resistance value and a low resistance value of the second magnetic tunnel junction structure 230.

The first peripheral circuit area PA1 and the second peripheral circuit area PA2 may be optimized to have a first reference resistance value and a second reference resistance value, respectively, by configuring different reference resistance circuits. For example, the first peripheral circuit area PA1 may include a first reference resistance circuit having a first reference resistance range, and the second peripheral circuit area PA2 may include a second reference resistance circuit having a second reference resistance range. Here, the first reference resistance range and the second reference resistance range may constitute different ranges.

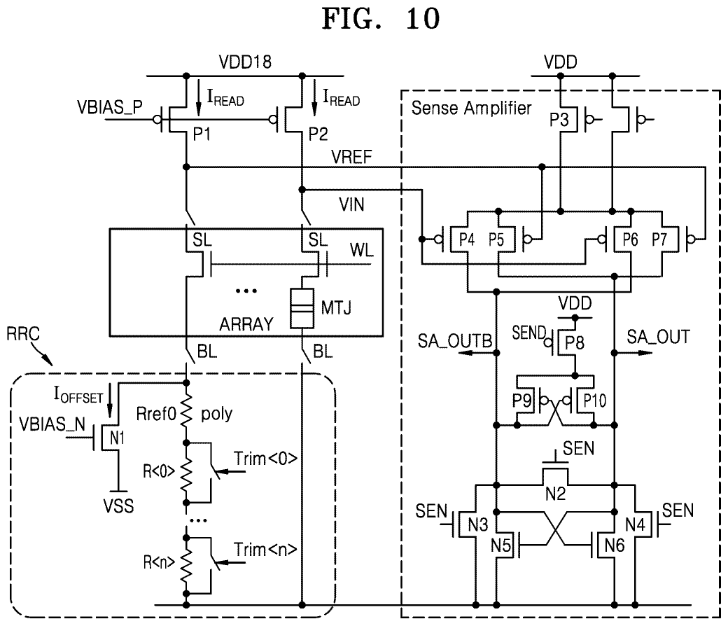

FIG. 10 is a circuit diagram illustrating an example methodology for optimizing a reference resistance range of a variable resistance memory device according to an embodiment.

Referring to FIG. 10, a reference resistance circuit RRC may include polyresistors (i.e., polysilicon resistors), and an optimized reference resistance value may be determined using a combination of resistances. The reference resistance circuit RRC may include a default resistance Rref0 and a plurality of auxiliary resistances R0 to Rn, and may have different resistance ranges. For example, if a high resistance value is 5000 Ω and a low resistance value is 1000 Ω, the default resistance Rref0 may be set to 2000 Ω, and the reference resistance circuit RRC may be configured to have a reference resistance range between about 2000 Ω and about 4000 Ω by combining multiple auxiliary resistances R0 to Rn. In this case, the reference resistance circuit RRC may be optimized such that the reference resistance value is, for example, 3000 Ω.

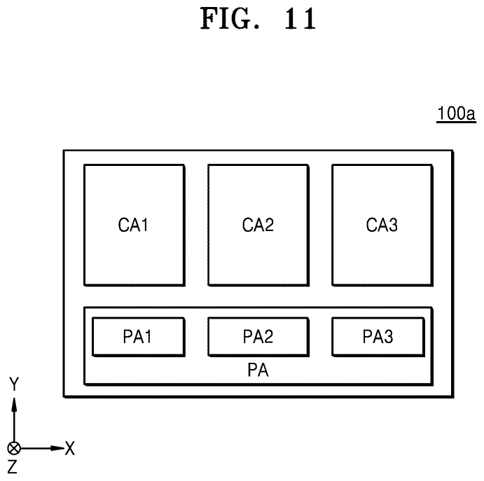

FIG. 11 is a schematic top plan view of a variable resistance memory device according to an embodiment.

Referring to FIG. 11, a variable resistance memory device 100a according to an embodiment may include a third cell area CA3 and a third peripheral circuit area PA3 connected to the third cell area CA3. The third cell area CA3 may have the same configuration as the first cell area CA1 and the second cell area CA2, but include a third magnetic tunnel junction structure (not explicitly shown) having a different size from those of the first magnetic tunnel junction structure 130 and the second magnetic tunnel junction structure 230 (see FIGS. 7 and 8). The third cell area CA3 may have a different contact size from that of the first cell area CA1 and the second cell area CA2 depending on a size of the third magnetic tunnel junction structure (not shown). Additionally, the third peripheral circuit area PA3 may have a third reference resistance value optimized according to the size of the third magnetic tunnel junction structure (not shown).

While FIG. 11 illustrates the variable resistance memory device 100a including three cell areas (CA1, CA2, CA3) and three peripheral circuit areas (PA1, PA2, PA3), the inventive concept is not limited thereto, and a variable resistance memory device may be modified in various ways to include two or more cell areas and two or more corresponding peripheral circuit areas.

While the inventive concept has been particularly shown and described with reference to embodiments thereof, it will be understood that various changes in form and details may be made therein without departing from the spirit and scope of the following claims.

What is claimed is:

1. A variable resistance memory device, comprising:
a first cell area comprising a first magnetic tunnel junction structure;
a second cell area comprising a second magnetic tunnel junction structure, the second magnetic tunnel junction structure having at least one dimension that is different from that of the first magnetic tunnel junction structure;
a first peripheral circuit area electrically connected to the first cell area and having a first reference resistance value; and
a second peripheral circuit area electrically connected to the second cell area and having a second reference resistance value different from the first reference resistance value.

2. The variable resistance memory device of claim 1, wherein
a first diameter of the first magnetic tunnel junction structure is greater than a second diameter of the second magnetic tunnel junction structure, and
the first reference resistance value is smaller than the second reference resistance value.

3. The variable resistance memory device of claim 2, wherein
the first magnetic tunnel junction structure and the second magnetic tunnel junction structure have a same vertical height.

4. The variable resistance memory device of claim 1, wherein
the first peripheral circuit area includes a first reference resistance circuit having a first reference resistance range, and the second peripheral circuit area includes a second reference resistance circuit having a second reference resistance range different from the first reference resistance range, and
the first reference resistance circuit is configured such that the first reference resistance value is between a high resistance value and a low resistance value of the first magnetic tunnel junction structure, and
the second reference resistance circuit is configured such that the second reference resistance value is between a high resistance value and a low resistance value of the second magnetic tunnel junction structure.

5. The variable resistance memory device of claim 1, wherein
the first magnetic tunnel junction structure has a first writing speed and first data retention characteristics, and
the second magnetic tunnel junction structure has a second writing speed faster than the first writing speed and second data retention characteristics lower than the first data retention characteristics.

6. The variable resistance memory device of claim 2, wherein
a lower portion of the first magnetic tunnel junction structure in the first cell area is electrically connected to a first cell plug through a first pad electrode,
a lower portion of the second magnetic tunnel junction structure in the second cell area is electrically connected to a second cell plug through a second pad electrode, and
a diameter of the second pad electrode is greater than a diameter of the first pad electrode.

7. The variable resistance memory device of claim 6, wherein
an average diameter of the second cell plug is greater than an average diameter of the first cell plug.

8. The variable resistance memory device of claim 6, wherein
an upper portion of the first magnetic tunnel junction structure is electrically connected to a bit line of the variable resistance memory device through a first contact structure, and
an upper portion of the second magnetic tunnel junction structure is electrically connected to a bit line through a second contact structure.

9. The variable resistance memory device of claim 8, wherein
an average diameter of the second contact structure is greater than an average diameter of the first contact structure.

10. The variable resistance memory device of claim 1, wherein the first cell area and the second cell area are on a same substrate.

11. The variable resistance memory device of claim 1, wherein
the first magnetic tunnel junction structure comprises a first lower electrode, a first resistance layer on the first lower electrode, and a first upper electrode on the first resistance layer, and
the second magnetic tunnel junction structure comprises a second lower electrode, a second resistance layer on the second lower electrode, and a second upper electrode on the second resistance layer.

12. The variable resistance memory device of claim 11, wherein
the first resistance layer comprises a first pinned layer, a first free layer, and a first barrier layer between the first pinned layer and the first free layer, and
the second resistance layer comprises a second pinned layer, a second free layer, and a second barrier layer between the second pinned layer and the second free layer.

13. The variable resistance memory device of claim 1, further comprising:
a third cell area including a third magnetic tunnel junction structure having at least one dimension that is different from those of the first magnetic tunnel junction structure and the second magnetic tunnel junction structure; and
a third peripheral circuit area electrically connected to the third cell area and having a third reference resistance value.

14. The variable resistance memory device of claim 1, wherein at least one of the first cell area and the second cell area includes a logic circuit.

15. A variable resistance memory device, comprising:
a first cell area comprising a first magnetic tunnel junction structure; and
a second cell area comprising a second magnetic tunnel junction structure,
wherein a lower portion of the first magnetic tunnel junction structure is electrically connected to a first cell plug through a first pad electrode, and a lower portion of the second magnetic tunnel junction structure is electrically connected to a second cell plug through a second pad electrode, and
a diameter of the first magnetic tunnel junction structure is greater than a diameter of the second magnetic tunnel junction structure, and a diameter of the second pad electrode is greater than a diameter of the first pad electrode.

16. The variable resistance memory device of claim 15, wherein
the first magnetic tunnel junction structure and the second magnetic tunnel junction structure have a same cross-sectional thickness.

17. The variable resistance memory device of claim 15, wherein
an average diameter of the second cell plug is greater than an average diameter of the first cell plug.

18. The variable resistance memory device of claim 15, wherein
an upper portion of the first magnetic tunnel junction structure is electrically connected to a bit line through a first contact structure, and an upper portion of the second magnetic tunnel junction structure is electrically connected to a bit line through a second contact structure, and
an average diameter of the second contact structure is greater than an average diameter of the first contact structure.

19. The variable resistance memory device of claim 15, wherein the first cell area and the second cell area are on a same substrate.

20. A variable resistance memory device, comprising:
a first cell area comprising a first magnetic tunnel junction structure;
a second cell area comprising a second magnetic tunnel junction structure having a different size from that of the first magnetic tunnel junction structure;
a first peripheral circuit area electrically connected to the first cell area and having a first reference resistance value; and
a second peripheral circuit area electrically connected to the second cell area and having a second reference resistance value different from the first reference resistance value,
wherein the first cell area comprises:
a first cell plug and a first lower insulating layer on the first cell plug;
a first pad electrode extending in the first lower insulating layer and electrically connecting a lower portion of the first magnetic tunnel junction structure to the first cell plug; and
a first contact structure electrically connecting an upper portion of the first magnetic tunnel junction structure to a bit line, and
wherein the second cell area comprises:
a second cell plug and a second lower insulating layer on the second cell plug;
a second pad electrode extending in the second lower insulating layer and electrically connecting a lower portion of the second magnetic tunnel junction structure to the second cell plug; and
a second contact structure electrically connecting an upper portion of the second magnetic tunnel junction structure to a bit line,
a first diameter of the first magnetic tunnel junction structure is greater than a second diameter of the second magnetic tunnel junction structure,
the first peripheral circuit area includes a first reference resistance circuit having a first reference resistance range, and the second peripheral circuit area includes a second reference resistance circuit having a second reference resistance range different from the first reference resistance range,
the first reference resistance circuit is configured such that the first reference resistance value is between a high resistance value and a low resistance value of the first magnetic tunnel junction structure,
the second reference resistance circuit is configured such that the second reference resistance value is greater than the first reference resistance value and is between a high resistance value and a low resistance value of the second magnetic tunnel junction structure, and
a diameter of the second pad electrode is greater than a diameter of the first pad electrode.
